(19) United States
(12) Patent Application Publication
(10) Pub. No.: US 2015/0122324 A1
(43) Pub. Date: May 7, 2015

(54) THIN-FILM PHOTOVOLTAIC DEVICE WITH OPTICAL FIELD CONFINEMENT AND METHOD FOR MAKING SAME

(71) Applicant: Brookhaven Science Associates, LLC, Upton, NY (US)

(72) Inventors: Matthew Eisaman, Port Jefferson, NY (US); Yutong Pang, Stony Brook, NY (US); Nanditha Dissanayake, Middle Island, NY (US)

(73) Assignee: Brookhaven Science Associates, LLC, Upton, NY (US)

(21) Appl. No.: 14/399,800

(22) PCT Filed: May 17, 2013
(86) PCT No.: PCT/US2013/041631

§ 371 Date: Nov. 7, 2014

Related U.S. Application Data
(60) Provisional application No. 61/648,654, filed on May 18, 2012.

(51) Int. Cl. H01L 51/44; H01L 51/00

(52) U.S. Cl. CPC H01L 51/44; H01L 51/442; H01L 51/444; H01L 51/0068; H01L 51/0057
USPC 136/256

(57) ABSTRACT

A photovoltaic device is provided that includes a first electrode layer and a second electrode layer; and a waveguiding structure disposed between the first electrode layer and the second electrode layer which includes an active layer adapted to convert photons transmitted to the active layer to electrons and holes. The waveguiding structure further includes a first layer adjacent the first electrode layer that includes a hole-conducting material having a first index of refraction, and a second layer including an electron-conducting material having a second index of refraction, wherein the active layer is disposed therebetween. The active layer has an index of refraction that is less than each of the first index of refraction and the second index of refraction and a thickness. The waveguiding structure is characterized by guided modes adapted for optically confining the photons within the active layer.

### CROSS-REFERENCE TO A RELATED APPLICATION

This application claims the benefit under 35 U.S.C. 119(e) of U.S. Provisional Application No. 61/648,654 filed on May 18, 2012, the disclosure of which is incorporated herein in its entirety.

### STATEMENT OF GOVERNMENT RIGHTS

This invention was made with Government support under contract number DE-AC02-98CH10886, awarded by the U.S. Department of Energy. The Government has certain rights in the invention.

### FIELD OF THE INVENTION

The present disclosure generally relates to the field of photovoltaic devices. More particularly, the present disclosure relates to photovoltaic devices with improved efficiency as power conversion apparatuses.

### BACKGROUND

Organic photovoltaic (OPV) (solar cell) devices hold promise as low-cost and highly scalable and sustainable alternatives to other types of photovoltaic technology. However, to date such devices have been limited by the overall power conversion efficiency (ratio of electrical power output by the device to solar power incident on the device) obtainable with organic polymer and small molecule (non-polymer) based photovoltaics (referred to collectively herein as organic photovoltaics, or “OPV's”). Generally, the overall power conversion efficiency of a photovoltaic device is dependent on the combined effects of the efficiency of coupling incident solar power into an active layer (the layer intended to absorb photons and convert these photons into electrons and holes) of the device, the optical absorption efficiency of the active layer, and the efficiency of extracting photo-generated charge carriers from the device. Though various methods of increasing the coupling efficiency are known, simultaneous optimization of both the optical absorption and charge carrier extraction still poses a challenge.

The number of photon-generated electron-hole pairs created in the active layer can be increased by increasing the optical absorption in the active layer. Complete light absorption in OPV cells typically requires active layer thicknesses of at least 150 nm. However, such thick active layers suffer from diminished charge collection and extraction. This is primarily due to the combined challenges of extremely short exciton diffusion length (generally about 10 nm for organic polymers), bimolecular recombination, and low free-carrier mobility, all of which limit the charge collection and current obtainable from the device. Therefore, a thin (<100 nm) active layer is desirable to optimize the extraction of photo-generated charge carriers, while a thicker layer of >100 nm is more desirable to increase optical absorption.

Various methods, primarily directed toward increasing the amount of incident radiation coupled into the active layer, have been proposed to help compensate for the reduced optical absorption of thinner active layers. For example, metallic nanostructures have been suggested to improve optical coupling and light absorption and thereby the overall efficiency of thin film photovoltaics. Such nanostructures can be optimized to effectively trap incoming light within the active layer of the cell through surface plasmon resonance at a metal-active layer interface, for example. While this approach has been applied to OPV devices with some success, the nanostructures primarily target the coupling of incident radiation into the device, and do not necessarily allow for very thin active layers. In particular, they do not address the combined challenges of exciton dissociation, charge recombination, and free carrier mobility, all three of which pose limits on increasing the overall power conversion efficiency of the cell.

Additional attempts to improve the absorption of photons in the active layer of OPVs have focused on increasing the optical path lengths in the active layer by scattering and/or internal reflection or waveguiding within the active layer. These approaches include positioning periodic nanostructures inside the OPV to efficiently couple incident sunlight into the guided modes of the waveguide/active layer structure. A typical such OPV device employing a nanostructure for enhanced optical absorption is described, for example, in Tumbleston, et. al, “Absorption and quasiguided mode analysis of organic solar cells with photonic crystal photoactive layers,” Optics Express 7670, Vol. 17, No. 9, 27 Apr. 2009. Referring to FIG. 1, the device 10 includes a glass substrate 40, a transparent upper electrode made of indium tin oxide (ITO) disposed thereon 30, and a hole-transport layer of poly(3,4-ethylenedioxythiophene) poly(styrenesulfonate) (PEDOT:PSS) 60 disposed on a photon-incident side of an active layer of poly(3-hexyl thiophene):[6,6]-phenyl C₆₁-butyric acid methyl ester (P3HT:PCBM) 50. The active layer forms part of a nanostructure for increasing light coupling into the active layer. The other part of the nanostructure (not shown) is a transparent electron transport layer with a low refractive index compared to P3HT:PCBM positioned between the active layer 50 and a metallic (aluminum) electrode 70.

None of these approaches allows sufficiently tight confinement of the electromagnetic field in thin (<100 nm) active layers to increase the optical absorption. In particular, as the active layer thickness is decreased to improve the extraction of photo-generated charge carriers, the absorption of guided modes becomes poor, and at some wavelengths and thicknesses guided modes are not supported at all. Therefore, it is not possible to improve the overall cell performance in these prior art devices, since a trade-off still exists between optical absorption and photo-generated charge carrier extraction. Other approaches have been proposed that use metal nanoparticles within the active layer to enhance field confinement. However, this technique presents other significant challenges such as charge trapping, shunting, and increase in the overall cost.

Accordingly, there is still a need for a photovoltaic device with sufficiently high absorption combined with improved extraction of photo-generated charge carriers to increase the overall power conversion efficiency of the device. There is also a need for photovoltaic devices with improved power conversion efficiency that can be economically manufactured.

### SUMMARY

The present disclosure relates to photovoltaic devices with improved efficiency as power conversion apparatuses. The present disclosure further relates to photovoltaic devices with a thin active layer within a waveguiding structure characterized by guided modes adapted for optical confinement of photons within the active layer. Accordingly, high absorption is provided within a thin active layer. The thin active layer also enhances extraction of photo-generated charge carriers. The resultant device offers improved overall power conversion efficiency through a combination of improved absorption by optical field confinement and extraction of photon-generated charge carriers in the thin active layer.

In one aspect, a photovoltaic device of the present disclosure includes a first electrode layer and a second electrode layer; and a waveguiding structure disposed between the first electrode layer and the second electrode layer, which includes an active layer adapted to convert photons transmitted to the active layer to electrons and holes. The waveguiding structure further includes a first layer comprising a hole-conducting material having a first index of refraction, and a second layer comprising an electron-conducting material having a second index of refraction, wherein the active layer is disposed therebetween. The active layer has an index of refraction that is less than each of the first index of refraction and the second index of refraction and has a thickness. The waveguiding structure is characterized by guided modes and is adapted for optically confining the photons within the active layer.

In another aspect, a photovoltaic device includes a first electrode layer; a coupling structure; and a waveguiding structure. The waveguiding structure includes a first layer, a semi-transparent second electrode layer, and an active layer for converting photons transmitted to the active layer to electrons and holes disposed between the semi-transparent second electrode layer and the first layer. The first layer is adjacent the first electrode layer and includes a hole-conducting material having a high index of refraction. The semi-transparent second electrode layer includes a metal and transmits incident radiation therethrough to the active layer. The active layer has an index of refraction that is less than the high index of refraction of the first layer and less than an index of refraction of the semi-transparent second electrode layer, the waveguiding structure being characterized by guided modes and adapted for optically confining the photons within the active layer. The coupling structure is disposed between the first electrode layer and the semi-transparent second electrode layer and couples photons incident on and transmitted through the semi-transparent second electrode layer of the photovoltaic device into the guided modes of the waveguiding structure.

In various aspects, a photovoltaic device of the disclosure includes a coupling structure disposed between the first electrode layer and the second electrode layer. The coupling structure can be formed in any two adjacent layers or can be an added layer.

In additional aspects, the coupling structure can include a nanostructured metal, and can include at least one of Al, Ag and Au.

In yet additional aspects, the coupling structure is periodic. In other aspects, the coupling structure is formed by nanotexturing to produce a random structure.

In one aspect, the hole-conducting material of a photovoltaic device of the disclosure can include at least one of vanadium pentoxide (V₂O₅), molybdenum oxide (MoO₃), tungsten(VI) oxide (WO₃), manganese oxide (MnO₂), copper oxide (CuO) and nickel(II) oxide (NiO).

In another aspect, the electron-conducting material of a photovoltaic device of the disclosure can include at least one of titanium(IV) oxide (TiO₂) and zinc oxide (ZnO).

In certain aspects, the active layer of a photovoltaic device of the disclosure can include an organic polymer, and can include at least one of P3HT:PCBM, poly[2,6-(4,4-bis-(2-ethylhexyl)-4H-cyclopenta[2,1-b;3,4-b′]dithiophene)-alt-4,7-(2,1,3-benzothiadiazole)]: phenyl-C₆₁-butyric acid methyl ester (PCPDTBT:PCBM) and poly[N-9′-heptadecanyl-2,7-carbazole-alt-5,5-(4′,7′-di-2-thienyl-2′,1′,3′-benzothiadiazole)]: phenyl-C₆₁-butyric acid methyl ester (PCDTBT:PCBM).

In additional aspects, the active layer of a photovoltaic device of the disclosure can include small molecules, and can include at least one of squaraine, subphthalocyanines (e.g., boron subphthalocyanine chloride) and the acenes, including but not limited to for example, pentacene, tetracene, rubrene and the like.

In still additional aspects, the active layer of a photovoltaic device of the disclosure can include one of a pyrite based absorber and a carbon nanotube based absorber.

In one aspect, the index of refraction of the active layer in a photovoltaic device of the disclosure is between about 1.0 and about 2.0, each of the first index of refraction and the second index of refraction is greater than about 2.0, and a differential index of refraction at each interface between the active layer and each of the first and the second layer is sufficient to optically confine the photons within the active layer.

In one aspect, the first electrode of a photovoltaic device of the disclosure includes at least one of indium tin oxide (ITO), fluorine doped tin oxide (FTO), Sn₂O, graphene, carbon nanotube film, and metal nanowire film.

In another aspect, the second electrode comprises at least one of Al, Ag, Au and graphene.

In yet another aspect, the photovoltaic device is adapted for extraction of holes from the first electrode layer and extraction of electrons from the second electrode layer. The second electrode layer can include at least one of ITO, FTO, Sn₂O, graphene, carbon nanotube film, and metal nanowire film, and the first electrode layer can include at least one of Al, Ag and graphene, wherein

In particular aspects, each of the first layer and the second layer has a thickness between about 10 nm and 60 nm.

In additional aspects, the thickness of the active layer is less than about 100 nm, and can be between about 10 nm and 60 nm.

The active layer is characterized by an absorption spectrum. In certain aspects, at least one of the first layer and the second layer is characterized by a different absorption spectrum, the at least one of the first layer and the second layer being adapted to convert incident photons to electrons and holes according to the different absorption spectrum. In one aspect, at least one of the first layer and the second layer can include one of nanocrystalline Si and amorphous Si. In another aspect, the first layer and/or the second layer can include one of PbSe and PbS nanocrystals.

The charge conducting materials of each of the first and second layers is characterized by a conductivity. In certain aspects, the hole conductivity of the hole-conducting material is above 10⁻³ S/cm, and the electron-conducting material is characterized by an electron conductivity above 10⁻³ S/cm.

In certain aspects of a photovoltaic device of the disclosure, at least one of the first and second layer is characterized by an index of refraction greater than 2.0 and a transmission of at least 90% over an AM1.5G solar spectrum.

The described embodiments of organic photovoltaic devices of the disclosure, which are to be read in conjunction with the accompanying drawings, are illustrative only and not limiting, having been presented by way of example only to describe the invention. As described herein, all features disclosed in this description may be replaced by alternative features serving the same or similar purpose, unless expressly stated otherwise. Therefore, numerous other embodiments of the modifications thereof are contemplated as falling within the scope of the present invention as defined herein and equivalents thereto.

### BRIEF DESCRIPTION OF THE DRAWINGS

FIG. 1 is a schematic of a cross-sectional view of a prior art photovoltaic device.

FIG. 2A is a schematic of a cross-sectional view of an embodiment of a photovoltaic device of the present disclosure.

FIG. 2B is a schematic of a cross-sectional view of another embodiment of a photovoltaic device of the present disclosure.

FIG. 3 is a schematic of a cross-sectional view of a general structure of a photovoltaic device for generating the plots of FIGS. 4-6.

FIG. 4A is a graphic representation of an absorption fraction (power absorbed in active layer divided by total incident power) of a photovoltaic device having the general structure of FIG. 1 as a function of an active layer thickness for normal incidence and for TE and TM modes that exist at a wavelength of 400 nm.

FIG. 4B is a graphic representation of the absorption fraction of a photovoltaic device having the general structure of FIG. 1 as a function of an active layer thickness for normal incidence and for TE and TM modes that exist at a wavelength of 600 nm.

FIG. 4C is a graphic representation of the absorption fraction of a photovoltaic device having the general structure of FIG. 1 as a function of an active layer thickness for normal incidence and for TE and TM modes that exist at a wavelength of 800 nm.

FIG. 4D is a graphic representation of the absorption fraction represented by FIGS. 4A-4C as a function of an active layer thickness for normal incidence and for TE and TM modes that exist from 300 nm to 800 nm integrated over the AM1.5G solar spectrum.

FIG. 5A is a graphic representation of the AM1.5G-integrated absorption fraction as a function of active layer thickness for: (1) TE₀ and TM₀ modes for the embodiment shown in FIG. 2 with no coupling layer 170, and using the optical properties listed in Table 1; and (2) normal incidence on the prior art photovoltaic device of FIG. 1.

FIG. 5B is a graphic representation of the AM1.5G-integrated absorption fraction as a function of active layer thickness for: (1) TE₀ and TM₀ modes for the embodiment shown in FIG. 2 with no coupling layer 170, no Bottom layer 130, and using the optical properties listed in Table 1; and (2) normal incidence on the prior art photovoltaic device of FIG. 1.

FIG. 6A is a graphic representation of the distribution of electric field magnitude squared |E|² for TE₀ and TM₀ modes at a wavelength of 500 nm through the embodiment shown in FIG. 3 with specific structure glass(semi-infinite)/ITO(140 nm)/Top(40 nm)/P3HT:PCBM(10 nm)/Bottom(40 nm)/Al(200 nm), with n_{Top}=n_{Bot}=3.5, k_{Top}=k_{Bot}=0, and using the optical properties listed in Table 1.

FIG. 6B is a graphic representation of the distribution of electric field magnitude squared |E|² for TE₀ and TM₀ modes at a wavelength of 500 nm through the embodiment shown in FIG. 3 with specific structure glass(semi-infinite)/ITO(140 nm)/Top(40 nm)/P3HT:PCBM(10 nm)/Al(200 nm), with n_{Top}=3.5, k_{Top}=0, and using the optical properties listed in Table 1.

FIG. 6C is a graphic representation of the distribution of electric field magnitude squared |E|² for TE₀ and TM₀ modes at a wavelength of 500 nm through the embodiment shown in FIG. 3 with specific structure glass(semi-infinite,)/ITO(140 nm)/Top(40 nm)/P3HT:PCBM(10 nm)/Bottom(40 nm)/Al(200 nm), with n_{Top}=n_{Bot}=1.8, k_{Top}=k_{Bot}=0, and using the optical properties listed in Table 1.

FIG. 6D is a graphic representation of the distribution of electric field magnitude squared |E|² for TE₀ and TM₀ modes at a wavelength of 500 nm through the embodiment shown in FIG. 3 with specific structure glass(semi-infinite,)/ITO(140 nm)/Top(40 nm)/P3HT:PCBM(10 nm)/Al(200 nm), with n_{Top}=1.8, k_{Top}=0, and using the optical properties listed in Table 1.

### DETAILED DESCRIPTION

The overall conversion efficiency of a photovoltaic device is generally dependent on the combined effects of the coupling efficiency into an active layer of the device, the optical absorption of the active layer, and the efficiency of charge extraction for generating a current from the device. Though various methods of increasing the coupling efficiency are known, simultaneous optimization of both the optical absorption and charge carrier extraction is not adequately addressed in the prior art.

The photovoltaic devices of the present disclosure incorporate a thin active layer sandwiched between higher-index layers to form a waveguiding structure characterized by guided modes adapted for optical confinement of photons within the active layer. The higher-index layers are also charge transport layers. By providing a thin active layer, the collection efficiency of the charge carriers produced is increased. By providing the thin active layer within a waveguiding structure characterized by guided modes tightly confined to the active layer, the optical absorption and conversion of photons to electron-hole pairs is increased to levels commensurate with conventional “thick” active layer photovoltaics. The resultant device offers an improved overall device efficiency through a combination of improved absorption and conversion of photons to charge-carriers in the active layer by optical field confinement, and a high charge collection efficiency and current production from the thin active layer.

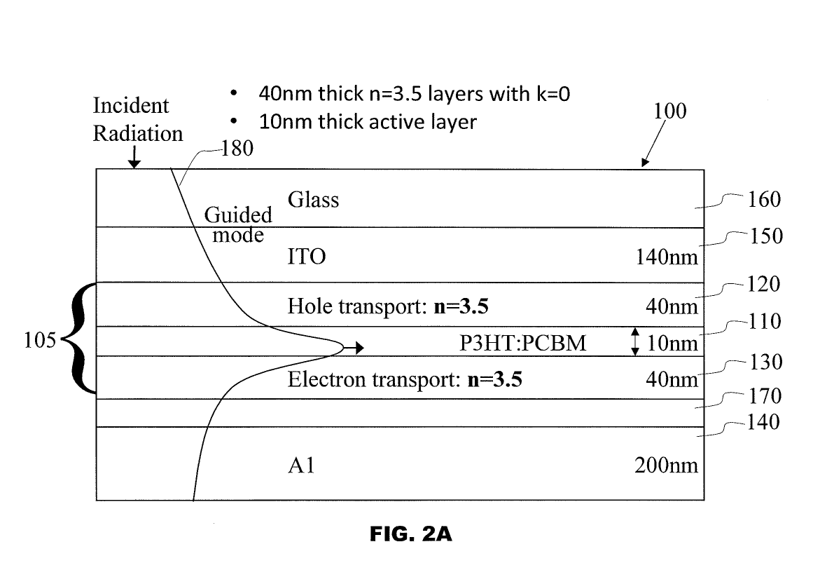

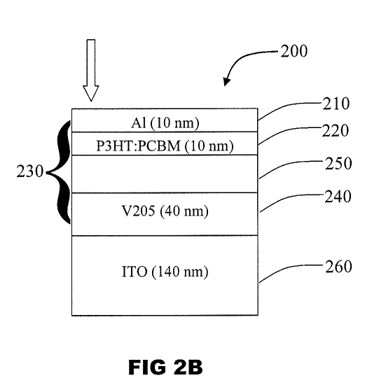

Referring to FIG. 2A, one embodiment of a photovoltaic device 100 of the present disclosure implements a waveguiding structure 105, generally referred to as a slot waveguide structure. The waveguiding structure 105 includes an active layer 110 disposed between a first layer 120 and a second layer 130, each of which has a higher index of refraction than that of the active layer 110. In some embodiments, the waveguiding structure 105 includes an active layer 110 disposed between a first layer 120 and a second layer 130, each of which has a higher index of refraction than that of the active layer 110 over a substantial portion of the AM1.5G solar spectrum, preferably, over the entire AM1.5G solar spectrum.

The active layer 110 is formed of a material suitable for converting photons that are transmitted to the active layer to electrons and holes and is characterized by an absorption spectrum which characterizes the absorption of photons as a function of incident wavelength. In preferred embodiments of the devices of the present disclosure, the active layer is formed of any suitable organic polymer or polymer blend for use in solar cells. P3HT:PCBM is one such material. In other embodiments, the active layer can include P3HT, PCPDTBT, PCDTBT, PCBM or blends thereof, including PCPDTBT:PCBM and PCDTBT:PCBM.

Small molecule (non-polymer) materials are also suitable active layer materials. Such materials include, but are not limited to, squaraine, subphalocyanine and acenes.

In other embodiments, the active layer can include a pyrite based absorber.

In yet additional embodiments, the active layer can include a carbon nanotube based absorber.

In certain embodiments of a photovoltaic device of the disclosure, it is desirable to choose materials comprising the first layer 120 and/or the second layer 130 that are also considered active layers and that are formed of another optically absorbing material, characterized by a different absorption spectrum. Such materials can include, but are not limited to, nano-crystalline silicon (nc-Si), amorphous silicon (a-Si), and PbSe and PbS nano-crystals.

The active layer 110 preferably has a thickness on the order of an exciton diffusion length of the active material to optimize charge collection and extraction efficiency. In certain embodiments, the thickness of active layer 110 is greater than zero and less than or equal to about 100 nm (i.e., 0 nm≧100 nm).

In other embodiments, the thickness of active layer 110 is greater than zero and less than or equal to about 60 nm (i.e., 0 nm≧60 nm). In still other embodiments, the thickness of the active layer 110 is in a range of about 1 nm, 5 nm or about 10 nm to about 60 nm. In yet additional embodiments, the thickness of the active layer can be between about 10 nm and about 60 nm.

Maintaining a thin active layer within the waveguiding structure 105 also enhances the support of guided modes 180 that are tightly confined to the active layer 110. The guided modes 180 are a result of the interaction between guided modes of the individual high-index layers 120 and 130. In particular, the materials comprising the first and second layers are preferably characterized by a sufficiently high index of refraction compared to that of the active layer to define an electric field discontinuity at each of the active layer/first layer and active layer/second layer interfaces sufficient to produce guided modes tightly confined to the thickness of the active layer 110. As discussed in more detail in the Example provided herein, the resultant structure 105 promotes optical confinement of the incident photons within the active layer.

In one embodiment, the active layer is formed of a material having an index of refraction that is less than or about equal to 2.0 over a selected absorption wavelength spectrum. In particular embodiments, the index of refraction is less than or about equal to 2.0 over at least 80% of the AM1.5G solar spectrum.

In an additional embodiment, the index of refraction of each of the first layer and the second layer is preferably greater than 2.0 over a selected absorption wavelength spectrum. In particular embodiments, the index of refraction is greater than or about equal to 2.0 over at least 80% of the AM1.5G solar spectrum.

In addition to being formed from high-index materials as part of the waveguiding structure 105, each of the first 120 and second layer 130 of the photovoltaic devices of the present disclosure have good charge transport characteristics. In the embodiment 100 of FIG. 2A, for example, the device 100 is a photovoltaic solar cell adapted for solar radiation incident on an upper transparent glass substrate 160 as shown. The substrate 160 can be any transparent substrate, such as glass, as are known to those of skill in the art for use in solar cells to be substantially transparent to incident solar radiation. The first layer 120 is positioned on a photon-incident side of the active layer 110. A first electrode 150 positioned between the substrate 160 and the first layer 120 is an anode formed of a substantially transparent layer of conductive oxide (TCO), for example, indium tin oxide (ITO). The second electrode 140 of the device 100 is a metal cathode of, for example, aluminum.

To promote efficient charge separation and collection, the first layer 120 is formed of a good hole-conducting material. Preferably, the first layer 120 has a hole conductivity above about 10⁻³ S/cm.

The second layer 130 adjacent the active layer 110 is preferably formed of a good electron transport (or hole blocking) material, preferably with an electron conductivity above about 10⁻³ S/cm. Accordingly, both the optical and electrical properties of the high-index layers of the photovoltaic devices of the present invention are optimized to enable a functioning and efficient photovoltaic device.

All of the layers at least on the photon-incident side of the active layer 110, including the first (hole-conducting) layer 120, are preferably substantially transparent over the AM1.5G solar spectrum. In certain embodiments, the first layer 120 has at least 90% transmission over the solar spectrum.

In another embodiment, both the first 120 and second layers 130 are substantially transparent to incident solar radiation. In additional embodiments, first 120 and second layers 130 preferably have a transmission of at least 90% over the AM1.5G solar spectrum.

Each of the first 120 and second 130 layers also preferably has a thickness optimized to support guided modes tightly confined to the active layer 110 to confine transmitted photons therein and to promote charge collection and extraction.

In one embodiment, at least one of the first layer 120 and second layer 130 has a thickness in the range of between about 10 nm and about 60 nm. In other embodiments, the thickness of at least one of the first layer 120 and second layer 130 is in the range of between about 30 nm and about 40 nm.

In other embodiments, at least one of the first layer 120 and second layer 130 has a thickness in the range of between about 30 nm and about 80 nm.

Particular challenges are posed in forming a photovoltaic device, particularly an organic photovoltaic device (OPV). In the devices of the present disclosure, a particularly difficult challenge is presented by requiring an organic active layer to be sandwiched between adjacent higher index layers. Not only must these high-index layers have optical characteristics appropriate for providing waveguiding, they must also be manufacturable without high temperature processing to prevent permanent damage to the sensitive thin organic active layer. In addition, the high-index layers must be fashioned of appropriate hole-conducting or electron-conducting materials for simultaneously forming both a charge transport and waveguide mode-confining layer. Finally, the device must be economically feasible.

It has been discovered that particular materials, especially, particular metal oxides which can be solution processed, can be used in combination with organic active layers to form devices with surprisingly high power conversion efficiency and are economically viable to produce.

In certain embodiments, a high-index hole-conducting layer (first layer 120 in the embodiment of FIG. 2A shown) of the waveguiding structure (105) can include at least one of vanadium pentoxide (V₂O₅), molybdenum oxide (MoO₃), tungsten(VI) oxide (WO₃), manganese oxide (MnO₂), copper oxide (CuO), and nickel (II) oxide (NiO).

In additional embodiments, a high-index electron-conducting layer (second layer 130 in the embodiment of FIG. 2A) of the waveguiding structure (105) can include at least one of titanium(IV) oxide (TiO₂) and zinc oxide (ZnO).

In particular embodiments, a photovoltaic device of the disclosure includes a slot waveguiding structure in accordance with the present disclosure, where a hole-conducting material of a first high-index layer is formed of at least one of vanadium pentoxide (V₂O₅), molybdenum oxide (MoO₃), and tungsten(VI) oxide (WO₃), and an electron-conducting material of a second high-index layer is formed of at least one of TiO₂ and ZnO.

Suitable anode materials (for first electrode 150, for example) for the photovoltaic devices of the present disclosure include ITO, FTO, Sn₂O, graphene, carbon nanotube film, and metal nanowire film.

Suitable cathode materials (for second electrode 140, for example, of FIG. 2A) for the photovoltaic devices of the present disclosure include Al, Ag, Au and graphene.

Referring still to the embodiment 100 of a photovoltaic device of the present invention, the photovoltaic device 100 preferably also includes a coupling structure 170 for coupling incident and transmitted radiation into the guided modes 180 of the waveguiding structure 105 to enhance the overall conversion efficiency of the device. This structure 170 can be, for example, a random nanotexturing on a surface of one of the existing layers in device 100, or a periodic nanostructure fashioned between an interface of the existing layers in device 100. This coupling structure 170 can also be provided as a separate nanostructured layer of, for example, a metal, such as Al, Ag, or Au. In one embodiment shown in FIG. 2A, the coupling structure 170 is provided between a second (lower) cathode layer 140 and the second high-index layer 130 of the waveguiding structure 150.

In different embodiments, however, a coupling structure can be embedded in any of the layers of the device 100, or disposed between any two layers, for example: between either electrode and an adjacent high-index layer; or between an electrode and a substrate.

It should be understood that the photovoltaic devices of the present invention are not limited to the particular embodiments shown. In particular, the present invention also includes photovoltaic devices having the waveguide structures of the present disclosure disposed in an inverted cell configuration, such that holes are extracted from a metal electrode and electrons from a transparent electrode. Referring to FIG. 2A, for example, in certain embodiments, the material of the upper high-index layer 120 can be an electron-conducting (hole blocking) material, such as titanium(IV) oxide (TiO₂) and zinc oxide (ZnO), and the lower high-index layer 130 can be formed of a hole-conducting material, such as vanadium pentoxide (V₂O₅), molybdenum oxide (MoO₃), tungsten(VI) oxide (WO₃), manganese oxide (MnO₂), copper oxide (CuO), and nickel (II) oxide (NiO).

Referring to FIG. 2B, an embodiment of a photovoltaic device 200 of the present disclosure includes a thin metallic, semi-transparent, upper electrode 210 on a photon-incident side of a thin active layer 220. The active layer 220 is disposed between the electrode layer 210 and a high-index layer 240, and has an index of refraction lower than the electrode layer 210 and the adjacent layer 240, to form a waveguiding structure 230 in accordance with the present invention that is characterized by guided modes adapted for optically confining the photons within the thickness of the active layer 220.

The higher index material of layer 240 is also an efficient hole-conducting material. As shown in FIG. 2B, and as also described in reference to the embodiment of FIG. 2A, the high-index hole-conducting material of layer 240 can be vanadium pentoxide (V₂O₅). In additional embodiments, the material of layer 240 can include molybdenum oxide (MoO₃), tungsten (VI) oxide (WO₃), manganese oxide (MnO₂), copper oxide (CuO), and nickel (II) oxide (NiO).

Both the metal of the electrode 210 and the hole-conducting material of layer 240 have a higher index of refraction than active layer 220 over a particular absorption wavelength spectrum. In preferred embodiments, the metal of the electrode 210 and the hole-conducting material of layer 240 have a higher index of refraction than active layer 220 over at least 80%, preferably over 90% of the AM1.5G solar spectrum. In this and similar embodiments of the present disclosure, optical confinement to the active layer 220 is enhanced by the waveguiding properties of the structure 230, and may also be enhanced by surface plasmon resonance at the metal 210/active 220 interface.

A coupling structure 250 is also preferably disposed between the upper electrode layer 210 and a lower electrode 260 for coupling incident photons into the guided modes of the waveguiding structure 230. In one embodiment, as shown, the coupling structure 250 can be disposed, for example, between the high-index layer 240 and active layer 220, so that light is coupled into the waveguiding structure 230 before reflecting from high-index layer 240. However, the structure 250 can also be embedded in a layer of the device or disposed between any interface between the upper electrode layer 210 and the electrode 260.

The active layer 220 shown in the particular embodiment of FIG. 2B has a thickness of about 10 nm to optimize charge collection and extraction efficiency. As also described in reference to FIG. 2A, in other embodiments, the thickness of active layer 220 is less than or equal to about 100 nm. In additional embodiments, the thickness is less than or equal to about 60 nm.

In still other embodiments, the thickness of the active layer 220 is in a range of about 5 nm or about 10 nm to about 60 nm.

The upper electrode 210 forms part of waveguiding structure 230. The differential in index of refraction at the interfaces between the active layer 220 and high-index layer 240 and between active layer 220 and upper electrode 210 is preferably maintained by choosing a material for active layer 220 that is less than or about equal to 2.0.

In one embodiment, the index of refraction of each of the upper electrode 210 and the high-index layer 240 is preferably greater than 2.0.

Upper electrode 210 in this embodiment can be formed of any suitable metal, including aluminum (Al), silver (Ag), or gold (Au) for example. Preferably, the upper electrode 210 is semi-transparent. In particular embodiments, upper electrode 210 has a thickness between about 10 nm and about 30 nm.

In some embodiments, the device is adapted to be semi-transparent over the AM1.5G solar spectrum. In these embodiments, the lower electrode 260 is formed of a suitable substantially transparent layer of a conductive oxide, such as ITO. Other suitable anode materials for electrode 260 include FTO, Sn₂O, graphene, carbon nanotube film, and metal nanowire film.

By incorporating the principles of a slot waveguide into an organic photovoltaic device (OPV) and surrounding a thin active layer with adjacent high-index layers, a photovoltaic device can be designed that supports guided modes with very tight optical confinement in the active layer. As a result, a strong optical absorption takes place in the active layer whose thickness is on the order of about 10 to about 40 nm, the exciton diffusion length in state-of-the-art organic materials. Accordingly, the OPVs of the present disclosure enable strong optical absorption in active layers that are thin enough to have electrical transport improvement as well as minimized recombination leading to a significant increase in the overall power conversion efficiency.

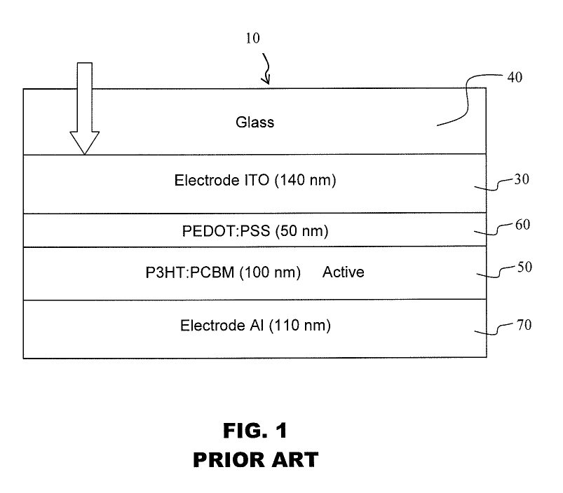

Unlike prior art devices, the present photovoltaic devices have increased optical absorption relative to normal incident absorption. For example, as described in the example below, it has been found that a calculated guided-mode absorption fraction for a 20 nm thick active layer in an organic photovoltaic device (OPV) of the present disclosure is about equal to the absorption fraction for normal incidence in a 100 nm thick active layer at normal incidence in a prior art OPV device 10 having the structure of FIG. 1.

### Example

### Calculated Absorption Fraction of a Device of the Present Disclosure Compared to a Prior Art Device

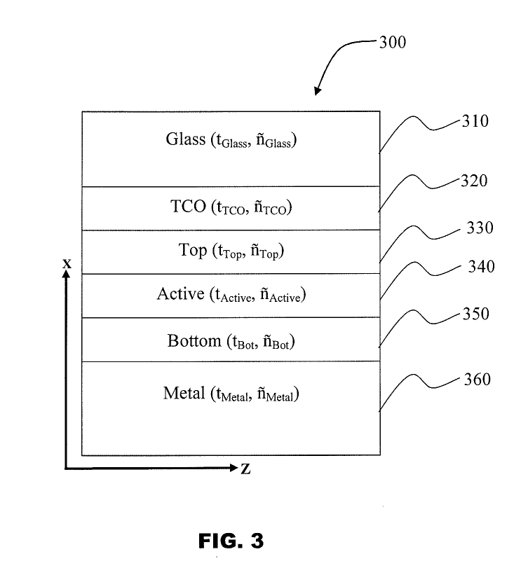

The following example provides calculations of absorption fraction (the power absorbed in an active layer divided by a total incident power) for a typical prior art device 10, such as that described by FIG. 1. For comparing the prior art device to the configuration of the present device, a general structure 300 shown in FIG. 3 is used for all calculations. Referring to FIG. 3, therefore, the prior art device 10 can be described for purposes of comparison as having: a substrate 310 of glass; an upper electrode of a TCO 320 of ITO of 140 nm thickness; a “top” layer 330 of a 40-nm thick layer of PEDOT:PSS; an active layer 340 of P3HT:PCBM, which is varied between 5-140 nm in thickness in the calculations; no “bottom” layer 350; and a metal lower electrode layer 360 of aluminum of 110 nm thickness.

A combination of the Transfer Matrix Method (TMM) and the Finite-Difference Time-Domain (FDTD) software from Lumerical Solutions is used herein to calculate the electromagnetic field distribution within an OPV structure for a given normally incident field. By solving the transfer equation, the modal-dispersion function X (β)=0 is obtained, where β is the effective index, with the zeros of this equation corresponding to the guided modes. This equation is solved using Newton's method, for example, as described in “Simple and Fast Numerical Analysis of Multilayer Waveguide Modes,” M. S. Kwon, S. Y. Shin, Opt. Comm. 233, 2004, pp. 119-126, which is incorporated herein by reference. Once the effective index is determined, it is substituted back into the expression for the electric field to calculate the electric field at any point in the structure for a given guided mode. The relative energy absorbed by each layer in the OPV structure is calculated from the electric field of each guided mode and used to calculate the fraction of light in a given guided mode that is absorbed by the active layer.

Table 1 lists the values, as provided in “Polymer-based solar cells,” A. Mayer, S. Scully, B. Hardin, M. Rowell, and M. McGehee. Mater. Today, 2007 10, 28-33, of the optical constants (real (n) and imaginary (k) refractive index) used in the calculations. It should be noted that the optical constants of many of these materials depend on the deposition and processing conditions, and in practice may differ from those listed in the table in Table 1.

TABLE 1

| | 300 nm | | 350 nm | | 400 nm | | 450 nm | |
|---|---|---|---|---|---|---|---|---|
| Material | n | k | n | k | n | k | n | k |
| ITO | 2.28 | 0.00 | 2.05 | 0.02 | 1.94 | 0.00 | 1.93 | 0.00 |
| P3HT:PCBM | 1.75 | 0.19 | 1.74 | 0.15 | 1.66 | 18.00 | 1.62 | 0.25 |
| PET:PSS | 1.70 | 0.02 | 1.62 | 0.01 | 1.57 | 0.01 | 1.54 | 0.01 |
| A1 | 0.28 | 3.61 | 0.38 | 4.25 | 0.49 | 4.87 | 0.62 | 5.48 |
| | 500 nm | | 550 nm | | 600 nm | | 650 nm | |
| Material | n | k | n | k | n | k | n | k |
| ITO | 1.88 | 0.01 | 1.82 | 0.01 | 1.77 | 0.01 | 1.72 | 0.02 |
| P3HT:PCBM | 1.87 | 0.38 | 2.09 | 0.41 | 2.12 | 0.32 | 2.04 | 0.04 |
| PET:PSS | 1.51 | 0.02 | 1.49 | 0.03 | 1.46 | 0.04 | 1.44 | 0.06 |
| A1 | 0.77 | 6.09 | 0.97 | 6.69 | 1.21 | 7.27 | 1.47 | 7.79 |

| | 700 nm | | 750 nm | | 800 nm | |
|---|---|---|---|---|---|---|
| Material | n | k | n | k | n | k |
| ITO | 1.66 | 0.01 | 1.61 | 0.01 | 1.55 | 0.01 |
| P3HT:PCBM | 1.94 | 0.01 | 1.90 | 0.00 | 1.87 | 0.00 |
| PET:PSS | 1.42 | 0.07 | 1.40 | 0.09 | 1.38 | 0.10 |
| Accordingly, | 1.86 | 8.31 | 2.36 | 8.58 | 2.68 | 8.46 |

### Calculations for a Prior Art OPV Structure

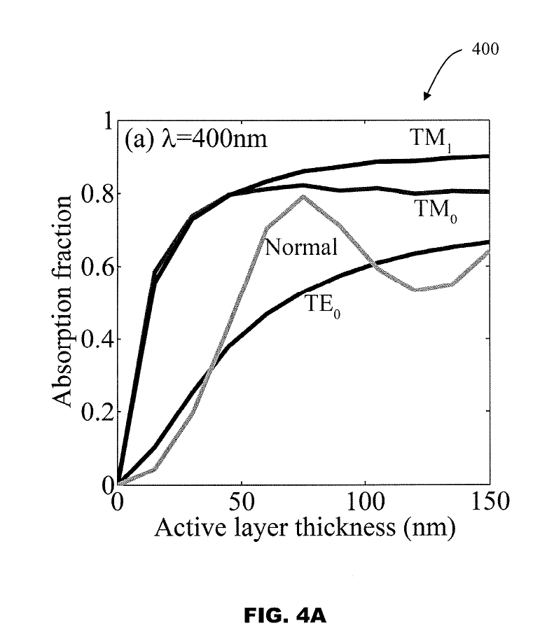

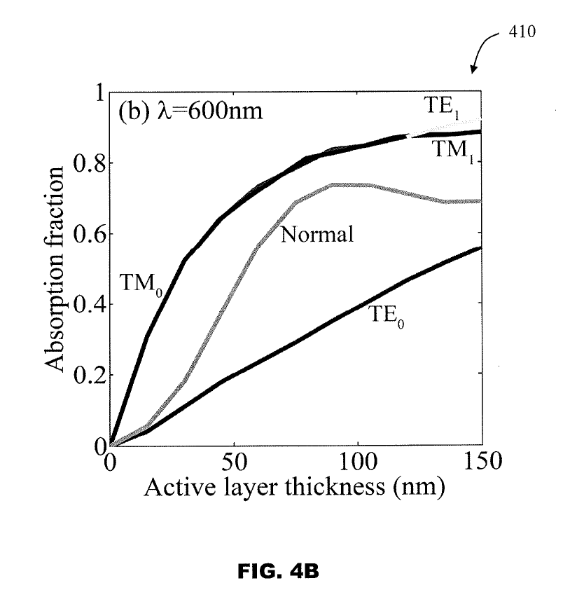

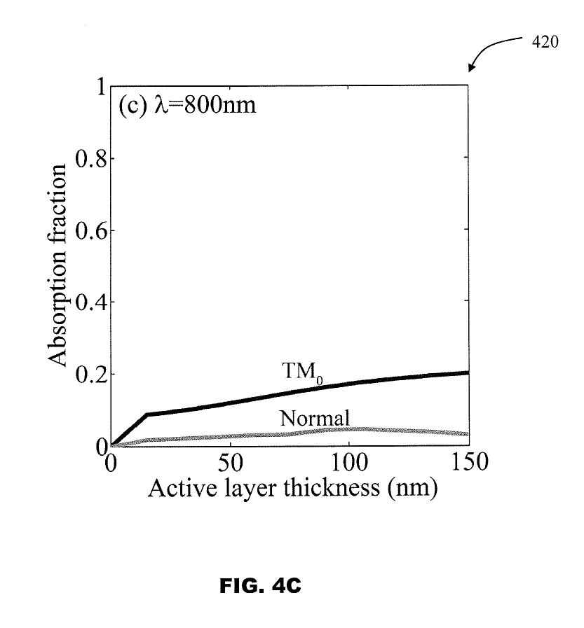

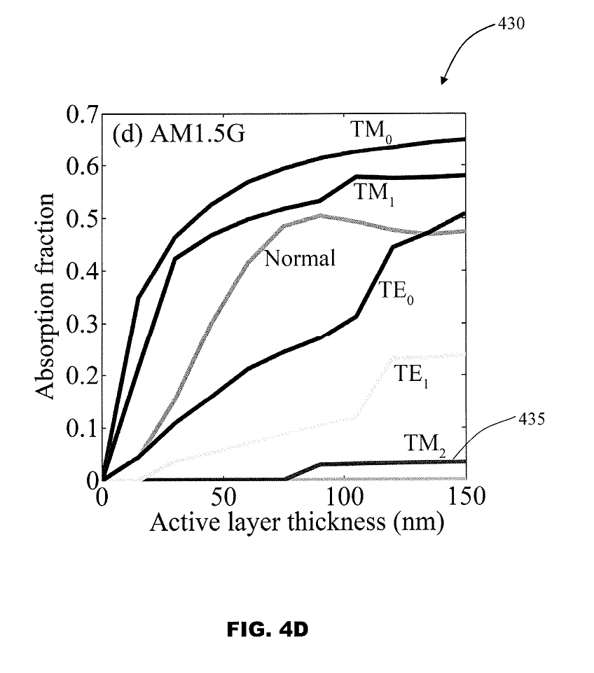

FIGS. 4A-4C show the fraction of light absorbed (at wavelengths λ=400 nm 400, 600 nm 410, and 800 nm 420, respectively) in the active layer of the “standard” OPV architecture described above in reference to the device 10 of FIG. 1 for P3HT:PCBM active-layer thicknesses ranging from 5 nm-140 nm. This calculation is performed for all guided modes that exist at a given thickness/wavelength combination, and also for normally incident light.

FIGS. 4A-4C show that, for a given wavelength, the number of modes increases as the active layer thickness increases, and at a given thickness the number of modes increases as the wavelength decreases. Referring to Table 1, P3HT:PCBM is by far the most strongly absorbing material, but there is also absorption in the ITO, PEDOT:PSS, and Al layers. For each active layer thickness, the results shown in FIG. 4A-4C are discretely integrated from 300 nm to 800 nm with 50 nm wide bins over the AM1.5G solar spectrum to obtain the total absorption 430, as shown in FIG. 4D, for each mode at a given thickness. The upper wavelength of the integration in FIG. 4D is limited to 800 nm, because the absorption strength of P3HT:PCBM drops steeply at 650 nm, and is very small for wavelengths larger than about 650 nm. The TM₂ mode 435 shown in FIG. 4D but not seen in FIGS. 4A-4C, comes from a calculated absorption in the wavelength range 300 nm-400 nm. To obtain the plot shown in FIG. 4D, for a given active layer thickness, modes that exist over only part of the integration range of 300 nm-800 nm are simply integrated over the part of the spectrum where they do exist.

As shown in FIGS. 4A-4D, TM modes have a consistently larger absorption fraction than normal incidence, with the relative difference increasing greatly as the active layer thickness decreases. In particular, FIG. 4D shows that while the TM₀ absorption fraction asymptotically approaches 0.65, a value approximately 1.4 times larger than that for normal incidence, at an active layer thickness of 10 nm the TM₀ absorption fraction is approximately 6 times larger than that of normal incidence. While not wishing to be bound by any particular theory, this behavior intuitively makes physical sense, since for active layers thicker than about 100 nm, most of the normally incident light is absorbed and thus less room for improvement exists by guiding modes in the active layer. In the case of thin active layers on the order of 10 nm thickness, however, very little light is absorbed for normal incidence, so that any mode that is tightly confined to the active layer (such as TM₀ in this case) should have greatly enhanced absorption relative to the normal incidence case.

As shown in FIG. 4D, a TM₀ guided mode in a standard OPV cell with a 40 nm-thick active layer will have the same absorption fraction as normal incidence on a standard cell with about 100 nm-thick active layer. Equivalent absorption fraction in a thinner active layer has the potential, therefore, to result in an OPV with overall improved power conversion efficiency due to the improved charge extraction properties of the thinner active layers. As described below, the thickness of the active layer with optical absorption equivalent to the normal-on-100 nm case can be reduced even further with optimization of the optical properties of the top 330 and bottom layers 350 shown in FIG. 3, in accordance with the devices of the present disclosure.

Referring still to FIGS. 4A-4D, in contrast to the behavior of TM modes, the TE modes have an absorption fraction that is less than or equal to the normal incidence case. The relatively strong absorption of TM modes relative to TE modes is due to the much stronger confinement of TM modes in the active layer of the cell for the standard OPV architecture considered here. Accordingly, by carefully choosing the optical properties and thicknesses of the top 330 and bottom layers 350 in accordance with the present device, the absorption fraction of both TM and TE modes can be increased by enabling tighter confinement of the guided mode in the active layer of the cell.

Thin OPV of the Present Disclosure with Embedded High-Index Layers

Results of calculations for various embodiments of the present disclosure are provided here for comparison to the prior art device described above. In particular, an absorption fraction is calculated for various parameters, while maintaining the top 330 and bottom layers 350 in the model as having large values of refractive index relative to that of the active layer 340 to maintain a slot waveguiding structure in accordance with the present disclosure.

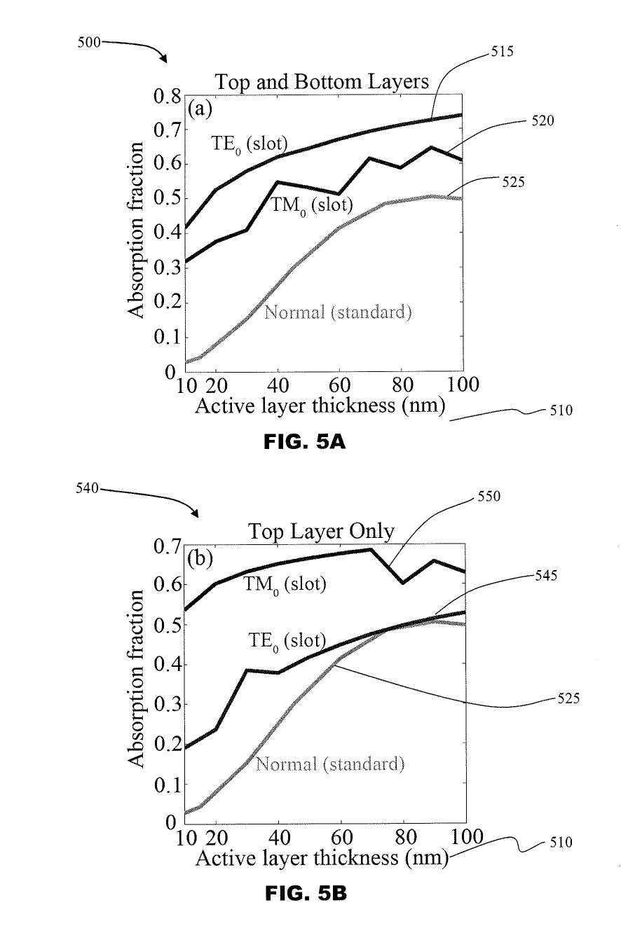

For example, FIG. 5A plots the calculated absorption fraction 500 averaged over the AM1.5G solar spectrum as a function of active-layer thickness in the active layer of a slot OPV structure (glass/ITO/top layer/P3HT:PCBM/bottom layer/Al) using t_{glass}=semi-infinite, t_{ITO}=140 nm, t_{Top}=40 nm, t_{active}=10 nm-100 nm (x-axis of plot), t_{Bot}=40 nm, t_{Al}=200 nm, n_{Top}=n_{bot}=3.5, and kₜₒₚ=k_{bot}=0 (no absorption in top 330 and bottom layers 350), and with the optical properties listed in Table 1. The absorption fraction is plotted as a function of active-layer thickness 510 for guided modes (TE₀ 515 labeled “TE₀ (slot)” and TM₀ 520 labeled “TM₀ (slot)”), and for normal incidence 525 on the standard OPV shown in FIG. 1 and studied in FIGS. 4A-4D (Top layer=PEDOT:PSS and no Bottom layer), labeled “Normal (standard).”

FIG. 5B plots the calculated absorption fraction 540 for a photovoltaic device of the present disclosure with the same structure as that shown in FIG. 5A except with no bottom layer 350 between the P3HT:PCBM active layer and the Al metal layer. The absorption fraction 540 is plotted as a function of active-layer thickness 510 for guided modes TE₀ 545 and TM₀ 550 and for normal incidence 525 on the standard OPV shown in FIG. 1 (see also FIGS. 4A-4D), with top layer PEDOT:PSS and no bottom layer, labeled “Normal (standard)” 525.

For a given slot OPV design, a useful metric for each mode is the slot OPV active layer thickness required for that mode to have an absorption fraction equal to that of normal incidence on the “Normal (standard)” where the active layer is 100 nm. The “Normal (standard)” with 100-nm active layer thickness serves as a benchmark for optical absorption in current commercial OPVs. Since charge extraction is expected to significantly improve for thin active layers (less than 100 nm), a thin slot OPV with guided-mode optical absorption equal to absorption for the “Normal (standard)” case is expected to have significantly improved overall power conversion efficiency than standard OPVs in use today.

For example, FIG. 5A plots the absorption fractions for the case of top 330 and bottom 350 layers having n_{Top}=n_{Bot}=3.5. As shown, the AM1.5G averaged absorption of the guided modes in a slot OPV is equal to the “Normal (standard)” absorption fraction 525 of about 0.5 for a slot OPV active-layer thickness of 20 nm and 40 nm for the TE₀ 515 and TM₀ 520 modes, respectively. Comparing this result to the guided-mode absorption for a standard OPV shown in FIG. 4D, it is shown that the presence of the high-index layers adjacent to the active layer in the slot OPV case especially improves the absorption fraction of the TE modes in thin active layers. While the high-index top and bottom layers in the slot OPV also improve the guided mode absorption of the TM modes relative to the standard OPV case shown in FIGS. 4A-4D, the improvement in the TE modes is even more pronounced. This may prove especially important from a practical perspective, since the selective coupling of incident sunlight into only TM modes is certainly less efficient than coupling into both TM and TE guided modes.

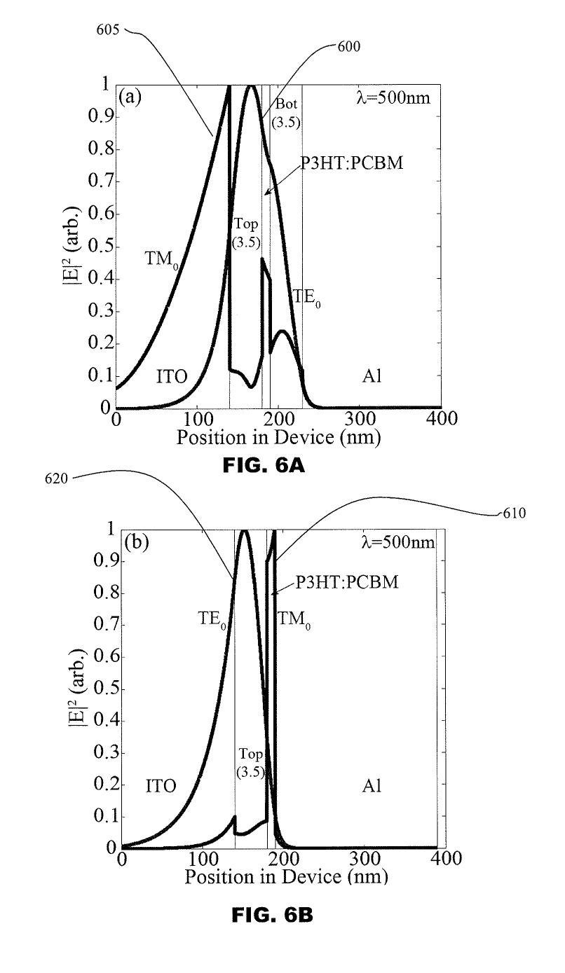

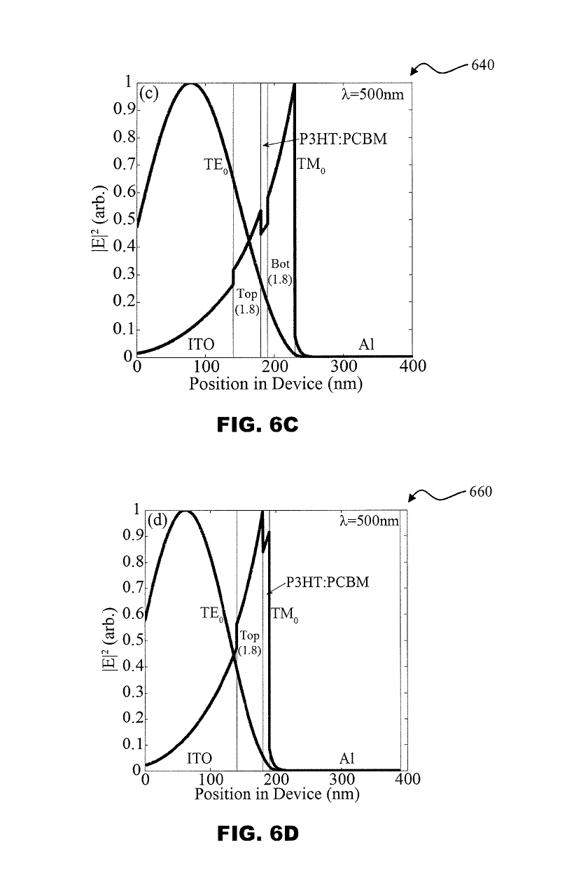

The behavior exhibited by the OPV structures observed in FIGS. 5A and 5B can be further understood by a comparison of the electric field distributions calculated for the structures plotted in FIGS. 6A-6D. FIGS. 6A-6D are plots of the distribution of the square of the electric-field magnitude (|E|²=|Eₓ|²+|E_{z}|²) for TE₀ and TM₀ modes at λ=500 nm throughout a 10 nm-thick-active-layer slot OPV device—glass(semi-infinite, not shown)/ITO (140 nm)/Top (40 nm)/P3HT:PCBM(10 nm)/Bottom (40 nm)/Al (200 nm, partially shown)—for the case of: (a) n_{Top}=n_{Bot}=3.5 (FIG. 6A); (b) n_{Top}=3.5, No Bottom layer (FIG. 6B); (c) n_{Top}=1.8, n_{Bot}=1.8 (FIG. 6C); and (d) n_{Top}=1.8, No Bottom layer (FIG. 6D). The maximum value of |E|² for each plotted mode is normalized to 1. FIG. 6A shows that the TE₀ electric field distribution curve 600 peaks in the top layer for n_{Top}=n_{Bot}=3.5. FIG. 6B shows that removing the bottom layer but keeping the top layer with the same n_{Top}=3.5 greatly increases the confinement of the TM₀ 610 in the active layer, but has the opposite effect on the TE₀ 620 mode.

Referring again to FIG. 6A, in regard to the thickness of the top 330 and bottom 350 layers, the absorption of the TE₀ mode 600 in the active layer is more sensitive than TM₀ 605 to absorption in the top and bottom layers. Referring to FIG. 6B, the TE₀ 620 active-layer absorption in a device having no bottom layer benefits from a thinner top layer. The ideal configuration for a given application will depend on many factors, including the ability to couple selectively into specific modes such as TM₀, in which case a top-layer-only design, like the embodiment shown in FIG. 2B, may be desired.

FIGS. 6C and 6D plot the square of the electric field magnitude for: (c) n_{Bot}=1.8 640, and (d) n_{Top}=1.8, no bottom layer 660, respectively. The effect of reducing the real part of the refractive index of the top and bottom layers from the value of 3.5 used in FIG. 6A and FIG. 6B to 1.8 used in FIGS. 6C and 6D is seen by comparison thereof. For the TE₀ mode, for example, generally, as the index of each of the top and bottom layers decreases, the peak of the mode moves from the top layer 330 towards the ITO layer 320, resulting in decreased field amplitude in the P3HT:PCBM active layer. For the TM₀ mode, the peak generally shifts toward the bottom layer 350.

These calculations show that the absorption fraction in cells formed in accordance with the present disclosure with thin active layers, less than 100 nm, including in a range of about 10-40 nm thick as provided in these examples, can be substantially equal to or greater than the absorption fraction of normally incident light on standard cells with thicker active layers (>100 nm). Accordingly, OPVs of the present disclosure achieve overall higher power conversion efficiency than prior art devices. In this context, an important metric for a given guided mode is the active layer thickness for which the guided mode absorption fraction is equal to the absorption fraction of normally incident light on a standard cell, such as that shown in FIG. 1, with a 100 nm-thick active layer.

### Experimental Tests

In preliminary experimental tests performed on the OPV architectures presented above, it is found that Prism coupling is an accurate method for the measurement of the effective index, β, of the guided modes of a slab waveguide. Prism coupling was used to measure the effective index of the TE₀ mode at 633 nm for a “Standard” OPV cell with the structure glass/ITO(140 nm)/PEDOT(40 nm)/P3HT:PCBM(100 nm)/Ag (9 nm), with the prism contacting the Ag side of the cell. The measured value of β_{TE0}=1.63 agrees very well with the calculated values of β_{TE0}=1.63 (calculated with TMM) and β_{TE0}=1.62 (calculated with FDTD).

Devices in accordance with embodiments of the present disclosure have been fabricated with a fixed thickness for very thin P3HT:PCBM layers of <10 nm maintained over the entire cell area. Functioning devices with active (P3HT:PCBM) layers as thin as 5 nm were successfully made and tested by (a) planarizing the rough underlying substrate using the hole-transport layer, (b) depositing P3HT:PCBM layer with low concentrations and high spin speed to enable uniform solvent evaporation, and (c) using conformal atomic layer deposition for the electron transport layer that is deposited on top of the P3HT:PCBM layer, thus preventing diffusion of the metal electrode material.

It should be apparent to those skilled in the art that the described embodiments of the present invention provided herein are illustrative only and not limiting, having been presented by way of example only. As described herein, all features disclosed in this description may be replaced by alternative features serving the same or similar purpose, unless expressly stated otherwise. Therefore, numerous other embodiments of the modifications thereof are contemplated as falling within the scope of the present invention as defined herein and equivalents thereto.

1. A photovoltaic device comprising:
a first electrode layer and a second electrode layer; and
a waveguiding structure disposed between the first electrode layer and the second electrode layer and comprising an active layer adapted to convert photons transmitted to the active layer to electrons and holes, the waveguiding structure further comprising a first layer adjacent the first electrode layer, the first layer comprising a hole-conducting material having a first index of refraction, and a second layer comprising an electron-conducting material having a second index of refraction, wherein the active layer is disposed therebetween; and
wherein the active layer has an index of refraction that is less than each of the first index of refraction and the second index of refraction and a thickness, the waveguiding structure being characterized by guided modes and adapted for optically confining the photons within the active layer.

2. The photovoltaic device of claim 1, further comprising a coupling structure disposed between the first electrode layer and the second electrode layer and adapted to couple incident photons into the guided modes of the waveguiding structure.

3. The photovoltaic device of claim 2, wherein the coupling structure is disposed between one of the first and second electrode layer and the waveguiding structure.

4. The photovoltaic device of claim 2, wherein the coupling structure is disposed between the active layer and one of the first layer and the second layer.

5. The photovoltaic device of claim 2, wherein the coupling structure is formed from at least one of the active layer, the first layer, and the second layer.

6. The photovoltaic device of claim 2, wherein the coupling structure comprises a nanostructured metal.

7. The photovoltaic device of claim 6, wherein the nanostructured metal includes at least one of Al, Ag and Au.

8. The photovoltaic device of claim 2, wherein the coupling structure is periodic.

9. The photovoltaic device of claim 2, wherein the coupling structure is formed by nanotexturing to produce a random structure.

10. The photovoltaic device of claim 1, further comprising a transparent substrate, wherein the first electrode layer is disposed on the transparent substrate, the photovoltaic device being adapted for solar radiation incidence on the substrate, and wherein the substrate, first electrode and first layer are substantially transparent over a AM1.5G solar spectrum.

11. The photovoltaic device of claim 10, further comprising a coupling structure disposed between the first electrode layer and the substrate and adapted to couple incident photons into the guided modes of the waveguiding structure.

12. The photovoltaic device of claim 1, wherein the hole-conducting material of the first layer comprises at least one of vanadium pentoxide (V₂O₅), molybdenum oxide (MoO₃), tungsten(VI) oxide (WO₃), manganese oxide (MnO₂), copper oxide (CuO) and nickel(II) oxide (NiO).

13. The photovoltaic device of claim 1, wherein the electron-conducting material of the second layer comprises at least one of titanium(IV) oxide (TiO₂) and zinc oxide (ZnO).

14. The photovoltaic device of claim 1, wherein the hole-conducting material of the first layer comprises at least one of vanadium pentoxide (V₂O₅), molybdenum oxide (MoO₃), and tungsten(VI) oxide (WO₃), and the electron-conducting material of the second layer comprises at least one of titanium(IV) oxide (TiO₂) and Zinc oxide (ZnO).

15. The photovoltaic device of claim 14, wherein the active layer comprises P3HT:PCBM.

16. The photovoltaic device of claim 1, wherein the active layer comprises an organic polymer.

17. The photovoltaic device of claim 16, wherein the active layer comprises at least one of poly(3-hexyl thiophene):[6,6]-phenyl C₆₁-butyric acid methyl ester (P3HT:PCBM), poly[2,6-(4,4-bis-(2-ethylhexyl)-4H-cyclopenta[2,1-b;3,4-b′]dithiophene)-alt-4,7-(2,1,3-benzothiadiazole)]: phenyl-C₆₁-butyric acid methyl ester (PCPDTBT:PCBM) and poly[N-9′-heptadecanyl-2,7-carbazole-alt-5,5-(4′,7′-di-2-thienyl-2′,1′,3′-benzothiadiazole)]: phenyl-C₆₁-butyric acid methyl ester (PCDTBT:PCBM).

18. The photovoltaic device of claim 1, wherein the active layer comprises small molecules.

19. The photovoltaic device of claim 18, wherein the active layer comprises at least one of squaraine, subphalocyanines and acenes.

20. The photovoltaic device of claim 1, wherein the active layer comprises one of a pyrite based absorber and a carbon nanotube based absorber.

21. The photovoltaic device of claim 1, wherein the index of refraction of the active layer is between about 1.0 and about 2.0, wherein each of the first index of refraction and the second index of refraction is greater than about 2.0, and wherein a differential index of refraction at each interface between the active layer and each of the first and the second layer is sufficient to optically confine the photons within the active layer.

22. The photovoltaic device of claim 1, wherein the first electrode comprises at least one of ITO, FTO, Sn2O, graphene, carbon nanotube film, and metal nanowire film.

23. The photovoltaic device of claim 22, wherein the second electrode comprises at least one of Al, Ag, Au and graphene.

24. The photovoltaic device of claim 1, wherein the second electrode comprises at least one of ITO, FTO, Sn2O, graphene, carbon nanotube film, and metal nanowire film, and the first electrode comprises at least one of Al, Ag and graphene, wherein the photovoltaic device is adapted for extraction of holes from the first electrode and extraction of electrons from the second electrode.

25. The photovoltaic device of claim 1, wherein each of the first layer and the second layer has a thickness between about 10 nm and 60 nm.

26. The photovoltaic device of claim 1, wherein the thickness of the active layer is less than about 100 nm.

27. The photovoltaic device of claim 1, wherein the thickness of the active layer is between about 10 nm and about 60 nm.

28. The photovoltaic device of claim 1, wherein the active layer is characterized by an absorption spectrum, and wherein at least one of the first layer and the second layer is characterized by a different absorption spectrum, the at least one of the first layer and the second layer being adapted to convert incident photons to electrons and holes according to the different absorption spectrum.

29. The photovoltaic device of claim 28, wherein the at least one of the first layer and the second layer comprises one of nanocrystalline Si and amorphous Si.

30. The photovoltaic device of claim 28, wherein the at least one of the first layer and the second layer comprises one of PbSe and PbS nanocrystals.

31. The photovoltaic device of claim 1, wherein the hole-conducting material of the first layer is characterized by a hole conductivity above 10-3 S/cm, and the electron-conducting material of the second layer is characterized by an electron conductivity above 10-3 S/cm.

32. The photovoltaic device of claim 31, wherein the first layer is characterized by an index of refraction greater than 2.0 and a transmission of at least 90% over an AM1.5G solar spectrum.

33. The photovoltaic device of claim 31, wherein the second layer is characterized by an index of refraction greater than 2.0 and a transmission of at least 90% over an AM1.5G solar spectrum.

34. A photovoltaic device comprising:
a first electrode layer;
a waveguiding structure comprising a first layer adjacent the first electrode layer and comprising a hole-conducting material having a high index of refraction, a semi-transparent second electrode layer comprising a metal and adapted for incident radiation being transmitted therethrough, and an active layer adapted to convert photons transmitted to the active layer to electrons and holes disposed between the semi-transparent second electrode layer and the first layer,
wherein the active layer has an index of refraction that is less than the high index of refraction of the first layer and less than an index of refraction of the semi-transparent second electrode layer, the waveguiding structure being characterized by guided modes and adapted for optically confining the photons within the active layer; and
a coupling structure disposed between the first electrode layer and the semi-transparent second electrode layer, the coupling structure coupling photons incident on and transmitted through the semi-transparent second electrode layer of the photovoltaic device into the guided modes of the waveguiding structure.

35. The photovoltaic device of claim 34, wherein the second electrode layer comprises one of gold, silver, and aluminum.

36. The photovoltaic device of claim 35, wherein the second electrode layer has a thickness of about 10 nm to about 30 nm, and wherein the active layer has a thickness between about 5 nm and about 60 nm.

37. The photovoltaic device of claim 35, wherein the active layer comprises one of P3HT:PCBM, PCPDTBT:PCBM and PCDTBT:PCBM.

38. The photovoltaic device of claim 35, wherein the hole-conducting material comprises at least one of vanadium pentoxide (V2O5), molybdenum oxide (MoO3), tungsten(VI) oxide (WO3), manganese oxide (MnO2), copper oxide (CuO) and nickel (II) oxide (NiO).

39. The photovoltaic device of claim 35, wherein the second electrode is a transparent conductive oxide, and wherein the photovoltaic device is adapted to be semi-transparent over an AM1.5G solar spectrum.

40. A power conversion apparatus comprising the photovoltaic device of claim 1.
